(19) United States
(12) Patent Application Publication
(10) Pub. No.: US 2011/0037092 A1
(43) Pub. Date: Feb. 17, 2011

(54) LIGHT-EMITTING ELEMENT

(76) Inventors: Atsuhiro Hori, Kagoshima (JP); Syuusaku Maeda, Kagoshima (JP); Hidenori Kamei, Kagoshima (JP)

Correspondence Address: MCDERMOTT WILL & EMERY LLP, 600 13TH STREET, NW, WASHINGTON, DC, 20005-3096, US

(21) Appl. No.: 12/989,630

(22) PCT Filed: Jun. 1, 2009
(86) PCT No.: PCT/JP2009/002436

§ 371 Date: Oct. 25, 2010

(30) Foreign Application Priority Data
Jun. 6, 2008 (JP) 2008-148787

(51) Int. Cl. H01L 33/60

(52) U.S. Cl. 257/98; 257/E33.067

(57) ABSTRACT

A light-emitting device includes an n-type semiconductor layer 13, a light-emitting layer 14, and a p-type semiconductor layer 15, which are sequentially stacked on a substrate 11; and a p-side electrode 16 formed on the p-type semiconductor layer 15. The p-side electrode 16 includes an adhesive layer 61 formed in contact with the p-type semiconductor layer 15, having a thickness ranging from 0.5 atomic layer to 1.5 atomic layer, and made of platinum; and a reflective layer 62 formed in contact with the adhesive layer 61, and made of a material containing silver.

### TECHNICAL FIELD

The present disclosure relates to light-emitting devices, and more particularly to light-emitting devices including reflective layers.

### BACKGROUND ART

A known light-emitting device includes an n-type semiconductor layer, a light-emitting layer, and a p-type semiconductor layer sequentially stacked on a transparent substrate, and light emitted from the light-emitting layer is extracted through the substrate. By forming a reflective layer on the p-type semiconductor layer, light radiated toward the p-type semiconductor layer can be reflected to the substrate, thereby improving light extraction efficiency.

In order to improve reflection efficiency of the reflective layer, the reflective layer is preferably made of silver which hardly absorbs light. However, if the reflective layer made of silver is directly formed on the p-type semiconductor layer, adhesiveness is not sufficient, thereby increasing electrical resistance. Thus, methods of reducing the resistance at the p-side electrode by forming a platinum layer between the reflective layer of made silver and the p-type semiconductor layer to improve the adhesiveness of the reflective layer have been researched. Although it is known that platinum strongly absorbs light, the light absorption of the platinum layer can be reduced by forming the platinum layer with a thickness ranging from 0.5 nm to 5 nm (see, e.g., Patent Document 1).

### Citation List

### Patent Document

PATENT DOCUMENT 1: Japanese Patent Publication No. 2004-63732

### SUMMARY OF THE INVENTION

### Technical Problem

However, the present inventors have found that conventional light-emitting devices cannot sufficiently reduce light absorption of platinum layers. Conventionally, it is believed that a platinum layer needs to have a thickness of 0.5 nm or more in view of reducing contact resistance by improving adhesiveness between a reflective layer and a p-type semiconductor layer. It is also believed that the light absorption of the platinum layer can be reduced when the thickness ranges from 0.5 nm to 5 nm. However, the present inventors have found that strong light absorption occurs even when the thickness of the platinum layer is in this range. They have also found that the thickness of the platinum layer needed to improve the adhesiveness of the reflective layer is not limited to the range.

It is an objective of the present invention to realize a light-emitting device with largely improved light absorption in an adhesive layer without reducing adhesiveness of a reflective layer based on the inventors' findings.

### Solution to the Problem

A light-emitting device according to the present invention includes an n-type semiconductor layer, a light-emitting layer, and a p-type semiconductor layer, which are sequentially stacked on a substrate; a reflective layer formed on the p-type semiconductor layer; and an adhesive layer formed between the p-type semiconductor layer and the reflective layer, and made of platinum. The adhesive layer has a thickness ranging from 0.5 atomic layer to 1.5 atomic layer.

### ADVANTAGES OF THE INVENTION

According to the present invention, a light-emitting device can be realized with largely improved light absorption in an adhesive layer without reducing adhesiveness of a reflective layer.

### BRIEF DESCRIPTION OF THE DRAWINGS

FIG. 1 is a graph illustrating the relationship between the thickness of an adhesive layer and a removal rate of a reflective layer.

FIG. 2 is a graph illustrating the relationship between the thickness of the adhesive layer and optical output.

FIG. 3 is a cross-sectional view illustrating an example light-emitting device.

FIGS. 4(a)-4(c) are cross-sectional views illustrating a manufacturing method of an example semiconductor device in order of steps.

FIGS. 5(a)-5(c) are cross-sectional views illustrating a manufacturing method of an example semiconductor device in order of steps.

### DESCRIPTION OF EMBODIMENTS

An example light-emitting device includes an n-type semiconductor layer, a light-emitting layer, and a p-type semiconductor layer, which are sequentially stacked on a substrate; and a p-side electrode formed on the p-type semiconductor layer. The p-side electrode includes an adhesive layer formed in contact with the p-type semiconductor layer, having a thickness ranging from 0.5 atomic layer to 1.5 atomic layer, and made of platinum (Pt); and a reflective layer formed in contact with the adhesive layer and made of a material containing silver (Ag).

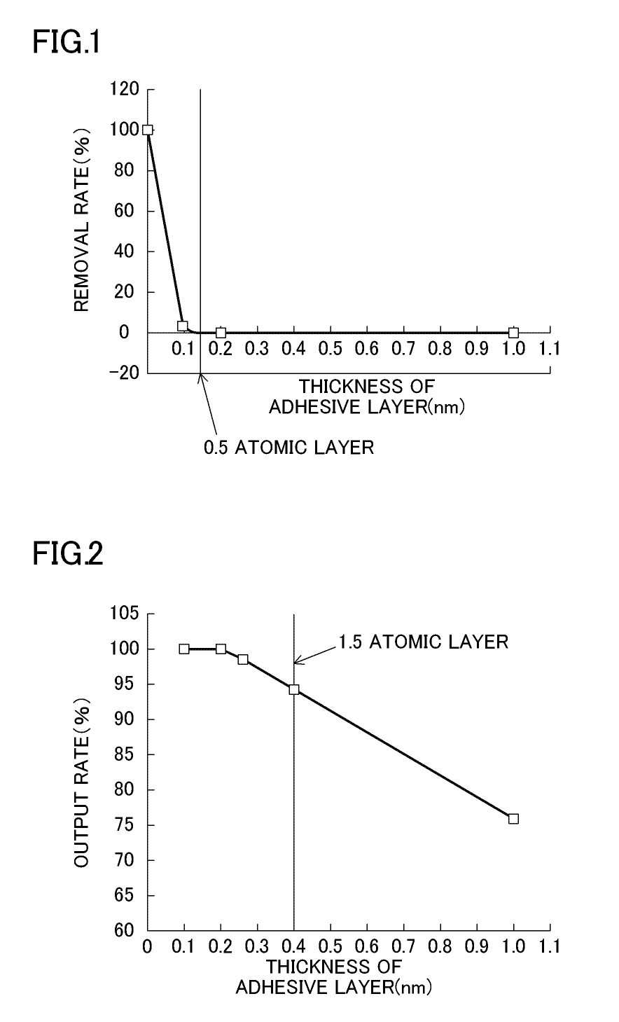

As shown in FIG. 1, when the thickness of the adhesive layer is smaller than 0.5 atomic layer, the function of the adhesive layer decreases so that the reflective layer is easily removed and the removal rate largely increases. Thus, the adhesive layer needs to have a large thickness to some extent. However, as shown in FIG. 2, when the thickness of the adhesive layer is large, the output rate largely decreases. If the output rate decreases to the level of about 90%, which is equivalent to the output level where the reflective layer is made of a material such as aluminum which is not easily removed, and there is no advantage in using silver. Therefore, the thickness of the adhesive layer made of platinum preferably ranges from 0.5 atomic layer, in which removal can be prevented, to 1.5 atomic layer, in which an output rate of 95% or more can be obtained.

The reflective layer may be made of silver or an alloy of silver. While silver is preferable in view of the reflectivity, migration can be reduced when an alloy of silver is used.

The reflective layer may be a multilayer of a plurality of layers including a layer of silver or an alloy of silver. If the layer of silver is exposed to the surface when forming the layers, the color of the surface of the silver layer is changed by oxygen ashing at a later stage. This may reduce reflectivity and increase resistance. At least one protective layer is formed on the silver layer to protect the silver layer, thereby reducing the reflectivity and increasing the resistance.

### Embodiment

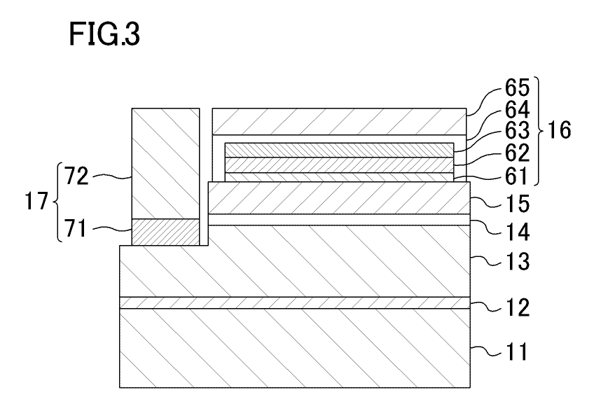

An embodiment of the present invention will be described hereinafter with reference to the drawing. FIG. 3 illustrates a cross-sectional structure of a light-emitting device according to the embodiment. As shown in FIG. 3, the light-emitting device of the embodiment includes an n-type semiconductor layer 13, a light-emitting layer 14, and a p-type semiconductor layer 15, which are sequentially formed on a substrate 11 with a buffer layer 12 interposed therebetween. The substrate 11 is transmissive to light, and may be a sapphire substrate, a SiC substrate, a GaN substrate or the like. The n-type semiconductor layer 13 is made of nitride semiconductor containing at least Ga and N, and contains n-type impurities such as Si or Ge. The n-type semiconductor layer 13 has a thickness of, for example, 2 μm. Furthermore, the n-type semiconductor layer 13 may be a multilayer formed by stacking a plurality of semiconductor layers.

The light-emitting layer 14 contains at least Ga and N, and contains In as necessary. By controlling the amount of In, a predetermined emission wavelength can be obtained. One or more pairs of an InGaN layer and a GaN layer may be stacked to form a multiple quantum well structure. The multiple quantum well structure provides the advantage of further improving brightness. Another nitride semiconductor layer may be formed between the light-emitting layer 14 and the n-type semiconductor layer 13.

The p-type semiconductor layer 15 contains at least Ga and N, and contains p-type impurities such as Mg. The p-type semiconductor layer 15 may have a thickness of, for example, 0.1 μm. Another nitride semiconductor layer may be formed between the light-emitting layer 14 and the p-type semiconductor layer 15. The p-type semiconductor layer 15 may be a multilayer formed by stacking a plurality semiconductor layers.

A p-side electrode 16 is formed on the p-type semiconductor layer 15. The p-side electrode 16 has a multilayer structure formed by stacking a plurality of metal layers. An adhesive layer 61, a reflective layer 62, an ashing damage barrier layer 63, a migration barrier layer 64, and a bonding pad 65 made of gold are sequentially formed from the side of the p-type semiconductor layer 15.

The adhesive layer 61 is made of platinum having a thickness ranging from 0.5 atomic layer to 1.5 atomic layer, and improves adhesiveness between the p-type semiconductor layer 15 and the reflective layer 62. The reflective layer 62 is made of silver having a thickness ranging from 5 nm to 2000 nm, and reflects light transmitted through the adhesive layer to the substrate 11. The reflective layer 62 may be made of silver or an alloy of silver. Also, the reflective layer 62 may be a multilayer formed by stacking a plurality of layers including a layer of silver or an alloy of silver. The ashing damage barrier layer 63 is made of chrome (Cr) and is formed to reduce damages in the reflective layer 62 made of silver during oxygen ashing. The thickness of the ashing damage barrier layer is preferably 30 nm or more so that the ashing damage barrier layer is formed uniformly on the reflective layer 62. The migration barrier layer 64 is made of titanium (Ti), and is formed to reduce the migration of the reflective layer 62 made of silver and to reduce emission defects. The migration barrier layer 64 is formed to cover not only the upper surface of the ashing damage barrier layer 63 but also the side surfaces of the adhesive layer 61, the reflective layer 62, and the ashing damage barrier layer 63. The bonding pad 65 is preferably made of gold (Au), and the thickness of the bonding pad 65 is preferably 800 μm or more.

The p-side electrode 16 is preferably provided over the entire surface of the p-type semiconductor layer 15 or over a region of 80% or more of the exposed area of the p-type semiconductor layer 15. The adhesive layer 61, the ashing damage barrier layer 63, the migration barrier layer 64 and the bonding pad 65 may contain other components as long as they contain the elements described above as an example. For example, as a platinum layer, a material into which other elements are mixed with an amount not affecting properties of platinum. Furthermore, the ashing damage barrier layer 63, the migration barrier layer 64, and the bonding pad 65 may be made of other materials as long as equivalent functions can be obtained.

The p-type semiconductor layer 15, the light-emitting layer 14, and a part of the n-type semiconductor layer 13 are selectively removed to form a portion in which the n-type semiconductor layer 13 is exposed. An n-side electrode 17 is formed on the exposed portion of the n-type semiconductor layer 13. The n-side electrode 17 includes a titanium layer 71 and a gold layer 72 sequentially formed on the n-type semiconductor layer 13.

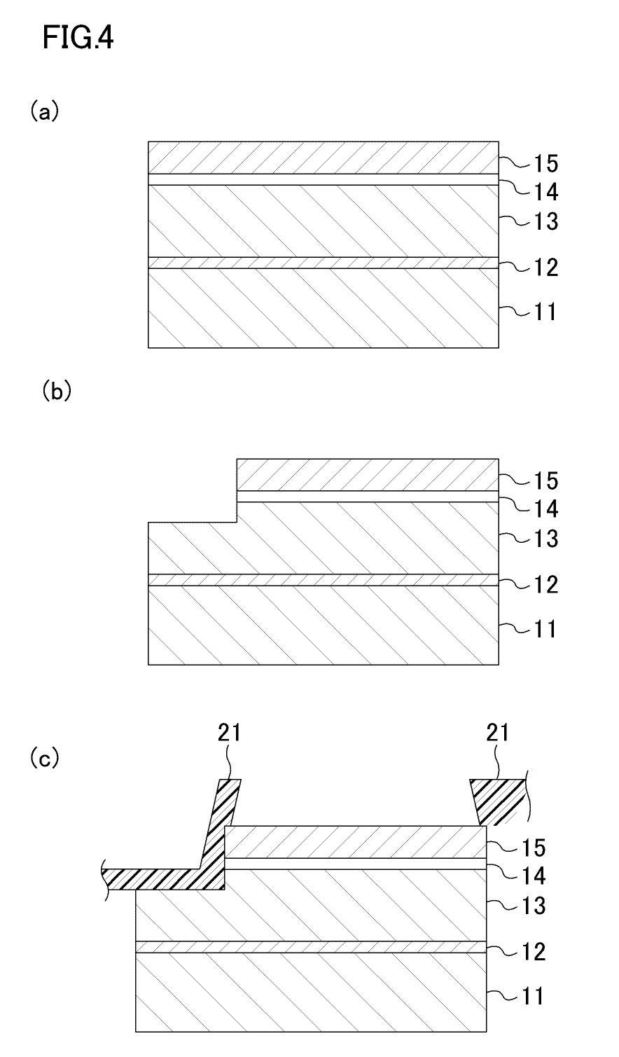

In a method of manufacturing the light-emitting device, first, as shown in FIG. 4(a), the buffer layer 12, the n-type semiconductor layer 13, the light-emitting layer 14, and the p-type semiconductor layer 15 are sequentially stacked on the substrate 11. Then, as shown in FIG. 4(b), the p-type semiconductor layer 15, the light-emitting layer 14, and a part of the n-type semiconductor layer 13 are selectively dry-etched to form the exposed portion of the n-type semiconductor layer 13. Next, as shown in FIG. 4(c), a resist film 21 having an opening exposing the upper surface of the p-type semiconductor layer 15 is formed. Then, the exposed portion of the p-type semiconductor layer 15 is cleaned with hydrofluoric acid solution to remove carbon and the like.

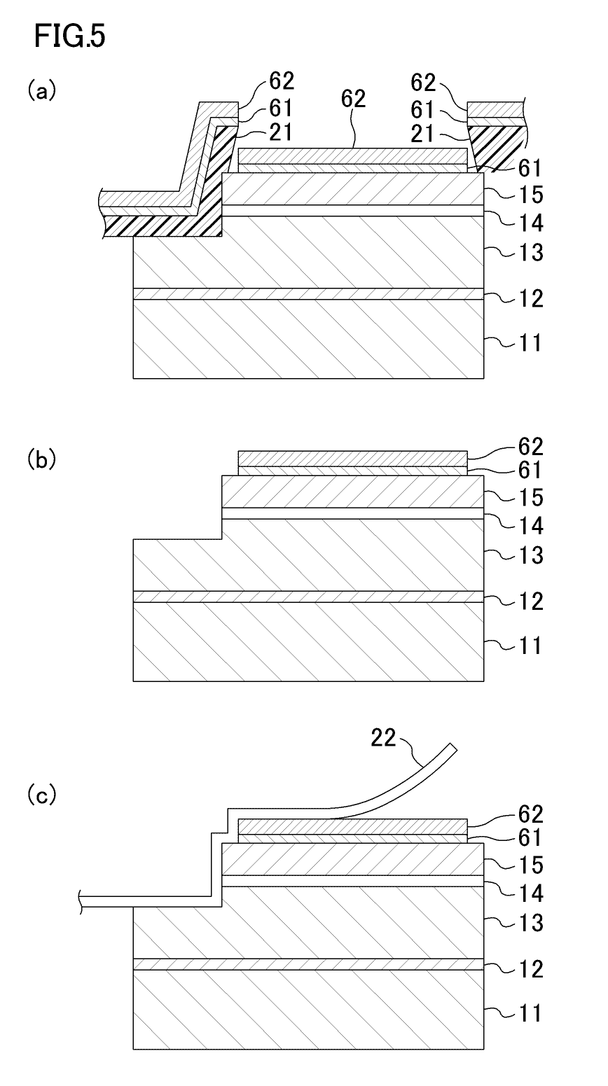

Next, as shown in FIG. 5(a), the adhesive layer 61 made of platinum and the reflective layer 62 made of silver are formed in the exposed portion of the p-type semiconductor layer 15. Then, as shown in FIG. 5(b), the resist film 21 is removed by organic cleaning. After that, as shown in FIG. 5(c), an adhesive sheet 22 is bonded to cover the entire surface of the substrate 11, and is then peeled off from an end to remove residues such as pieces of the resist film and the electrode, which remain unremoved in the organic cleaning. Then, although it is not shown in the figure, the remaining portion of the p-side electrode 16, the n-side electrode 17, and the like are formed and separated into pieces as necessary.

When the adhesiveness between the p-type semiconductor layer 15 and the reflective layer 62 is weak, the reflective layer 62 is removed when removing the residues using the adhesive sheet 22. However, the light-emitting device of this embodiment includes the adhesive layer 61 of platinum. Thus, the removal of the reflective layer 62 can be reduced. FIG. 1 illustrates the relationship between the thickness of the adhesive layer 61 and the removal rate. When the adhesive layer 61 is not formed, the removal rate is 100%. The removal can be reduced by forming the adhesive layer 61. However, when the thickness of the adhesive layer 61 is 0.1 nm, slight removal is found. Thus, in order to prevent the removal of the reflective layer 62, the thickness of the adhesive layer is preferably 0.13 nm or more. This corresponds to 0.5 atomic layer of platinum.

On the other hand, when the thickness of the adhesive layer 61 is increased, optical output is reduced because light is absorbed by the adhesive layer 61. FIG. 2 illustrates the relationship between the thickness of the adhesive layer 61 and the optical output. As described above, when the adhesive layer 61 is not formed, the removal rate of the reflective layer 62 is 100%, and a light-emitting device cannot be formed. Thus, in FIG. 2, the output rate is provided on the assumption that the optical output is 100% where the thickness of the adhesive layer 61 is 0.1 nm. As shown in FIG. 2, with an increase in the thickness of the adhesive layer 61, the optical output significantly decreases. When the thickness of the adhesive layer 61 is 1 nm, the output rate decreases to about 75%. The output rate is 95% where the thickness of the adhesive layer 61 is about 0.4 nm. This corresponds to 1.5 atomic layer of platinum.

From the above results, in order to reduce the removal of the reflective layer 62 and to mitigate a decrease in the optical output, the thickness of the adhesive layer 61 preferably ranges from 0.13 to 0.4 nm, i.e., from 0.5 atomic layer to 1.5 atomic layer.

The reflective layer 62 is preferably made of silver in view of the reflectivity, but may be made of an alloy of silver. In particular, by using an alloy containing silver, and bismuth (Bi), neodymium (Nd), copper (Cu), palladium (Pd), or the like; the advantage of reducing migration can be more fully appreciated.

Note that, when the thickness of the reflective layer 62 is about 5 nm or less, sufficient reflective properties cannot be easily obtained. Also, when the thickness is 2000 nm or more, the reflective properties do not change to require more evaporative materials needed to form the layers and to increase time required for a process of evaporating an Ag layer, thereby increasing manufacturing costs. Therefore, the thickness of the reflective layer 62 preferably ranges from 5 nm to 2000 nm.

A manufacturing method of the example light-emitting device will be described further in detail using an embodiment. While in the following description, metal organic vapor deposition is used as a method of growing a nitride semiconductor layer; molecular beam epitaxy, metal organic molecular beam epitaxy, and the like may also be used.

### Example

First, a substrate 1 of GaN of which surface is finished into a mirror surface is mounted on a substrate holder in a reaction tube. Then, the temperature of the substrate 1 is maintained at 1050° C., and the substrate 1 is heated for five minutes while allowing nitrogen, hydrogen, and ammonia to flow, thereby removing moisture and dirt such as organic substances adhered to the surface of the substrate 1.

Then, while allowing nitrogen and hydrogen to flow as carrier gas; ammonia, trimethylgallium (TMG) and SiH₄ are supplied to grow the n-type semiconductor layer 13 made of GaN doped with Si, and having a thickness of 2 μm.

After growing the n-type semiconductor layer 13, the supply of TMG and SiH₄ is stopped, and the temperature of the substrate 11 is decreased to 750° C. At the temperature of 750° C., ammonia, TMG, and trimethylindium (TMI) are supplied while allowing nitrogen to flow as carrier gas to grow the light-emitting layer 14 having a single quantum well structure made of undoped InGaN with a thickness of 2 nm.

After growing the light-emitting layer 14, the supply of TMI is stopped, and an interlayer (not shown) of undoped GaN with a thickness of 4 nm is grown while raising the temperature of the substrate 11 to 1050° C. After the temperature of the substrate reaches 1050° C., the p-type semiconductor layer 15 is grown. The p-type semiconductor layer 15 includes a p-type cladding layer with a thickness of 0.05 μm, and a p-type contact layer with a thickness of 0.05 μm. Specifically, ammonia, TMG, trimethylaluminum (TMA), and cyclopentadienyl magnesium (Cp₂Mg) are supplied while allowing nitrogen and hydrogen to flow as carrier gas to grow the p-type cladding layer having the thickness of 0.05 μm and made of AlGaN. Then, while allowing nitrogen gas and hydrogen gas to flow as carrier gas with the temperature of the substrate 11 maintained at 1050° C.; ammonia, TMG, TMA, and Cp₂Mg are supplied to grow the p-type contact layer having the thickness of 0.05 μm and made of AlGaN.

Next, the supply of TMG, TMA, and Cp₂Mg is stopped, the substrate 11 is cooled to room temperature while allowing nitrogen gas and ammonia to flow, then the substrate 11 on which nitrogen semiconductors are stacked is taken out from the reaction tube.

A SiO₂ film is deposited by CVD, on the surface of the multilayer structure of the nitride semiconductors formed as above without performing extra annealing. Then, the multilayer structure is patterned into a substantially rectangle shape by photolithography and wet etching to form a SiO₂ mask for etching. After that, the p-type semiconductor layer 15, the interlayer, the light-emitting layer 14, and a part of the n-type semiconductor layer 13 are selectively removed to the depth of about 0.4 μm by reactive ion etching to form the exposed portion of the n-type semiconductor layer 13.

Next, after removing the SiO₂ mask for etching by wet etching, photoresist is applied onto the surface of the multilayer structure, and then, the photoresist applied onto the surface of the p-type semiconductor layer 15 is selectively removed by photolithography to expose about 80% or more of the surface of the p-type semiconductor layer 15.

Then, the substrate 11 provided with the multilayer structure is mounted in a chamber of a vacuum deposition apparatus. After evacuating the chamber to 2×10⁻⁶ Torr or less, the adhesive layer 61 having a thickness of 0.2 nm and made of platinum is deposited on the surface of the p-type semiconductor layer 15 and on the photoresist by electron beam deposition. Then, the reflective layer 62 having a thickness of 100 nm and made of silver is deposited, and further, the ashing damage barrier layer 63 having a thickness of 30 nm and made of Cr is deposited.

Next, the substrate 11 provided with the multilayer structure is taken out from the chamber; the adhesive layer 61, the reflective layer 62, and the ashing damage barrier layer 63 on the photoresist are cleaned away together with the photoresist. As a result, a part of the p-side electrode 16, in which the adhesive layer 61, the reflective layer 62, the ashing damage barrier layer 63 are sequentially stacked, is formed on the p-type semiconductor layer 15. Then, after bonding the adhesive sheet onto the entire surface of the substrate 11 provided with the multilayer structure, the adhesive sheet is peeled off from an end, thereby removing the residues of the photoresist and the like which remain unremoved by the cleaning. Since the adhesive layer 61 is formed between the p-type semiconductor layer 15 and the reflective layer 62, the reflective layer 62 is not removed even when the residues are removed with the adhesive sheet, and the reflective layer of the p-side electrode 6 can remain stacked.

Then, the photoresist is applied onto the surface of the multilayer structure to form by photolithography, a resist mask exposing a part of the exposed portion of the n-type semiconductor layer 13, a part of the p-type semiconductor layer 15, the upper surface of the ashing damage barrier layer 63, and the side surfaces of the adhesive layer 61, the reflective layer 62, and the ashing damage barrier layer 63.

Next, the substrate 11 provided with the multilayer structure is mounted in the chamber of the vacuum deposition apparatus, the chamber is evacuated to 2×10⁻⁶ Torr or less. After that, a titanium layer with a thickness of 150 nm, and further, a gold layer with a thickness of 1.5 μm are deposited by electron beam deposition.

Then, the substrate 11 provided with the multilayer structure is taken out from the chamber, and the Ti layer and the Au layer on the photoresist are removed together with the photoresist, thereby forming the titanium layer 71 and the gold layer 72 of the n-side electrode 17, and the migration barrier layer 64 and the bonding pad 65 of the p-side electrode 16.

After that, the back surface of the substrate 11 is polished to a thickness of about 100 μm, and is separated into chips by scribing.

The light-emitting device obtained as described above is bonded with Au bumps, onto a Si diode having a pair of positive and negative electrodes, with the surface with the electrode facing downward. At this time, the light-emitting device is mounted so that the p-side electrode 16 and the n-side electrode 17 of the light-emitting device are coupled to the positive and negative electrodes of the Si diode, respectively. Then, the Si diode provided with the light-emitting device is mounted on a stem with Ag paste, the positive electrode of the Si diode is connected to an electrode on the stem with a wire, then resin molding is performed to manufacture a light-emitting diode.

When the obtained light-emitting diode is driven by a forward bias current of 350 mA, the forward bias operation voltage is about 3.7 V, and a light-emitting output (total radiant flux) is 253 mW. As such, in the light-emitting device of this embodiment, by forming the adhesive layer with a thickness ranging from 0.5 atomic layer to 1.5 atomic layer, light absorption of the adhesive layer can be reduced without decreasing adhesiveness of the reflective layer, thereby improving light extraction efficiency.

### INDUSTRIAL APPLICABILITY

The present invention largely improves light absorption of an adhesive layer without reducing adhesiveness of a reflective layer, and is thus, useful as a light-emitting device having a reflective layer.

### DESCRIPTION OF REFERENCE CHARACTERS

11 Substrate
12 Buffer Layer
13 N-Type Semiconductor Layer
14 Light-Emitting Layer
15 P-Type Semiconductor Layer
16 P-Side Electrode
17 N-Side Electrode
21 Resist Film
22 Adhesive Sheet
61 Adhesive Layer
62 Reflective Layer
63 Ashing Damage Barrier Layer
64 Migration Barrier Layer
65 Bonding Pad
71 Titanium Layer
72 Gold Layer

1. A light-emitting device, comprising:
an n-type semiconductor layer, a light-emitting layer, and a p-type semiconductor layer, which are sequentially stacked on a substrate; and
a p-side electrode formed on the p-type semiconductor layer, wherein
the p-side electrode includes
an adhesive layer formed in contact with the p-type semiconductor layer, having a thickness ranging from 0.5 atomic layer to 1.5 atomic layer, and made of platinum, and
a reflective layer formed in contact with the adhesive layer, and made of a material containing silver.

2. The light-emitting device of claim 1, wherein
the reflective layer is made of silver or an alloy of silver.

3. The light-emitting device of claim 1, wherein
the reflective layer is a multilayer of a plurality of layers including a layer made of silver or an alloy of silver.
